(19) United States
(12) Patent Application Publication
(10) Pub. No.: US 2017/0194392 A1
(43) Pub. Date: Jul. 6, 2017

(54) ELECTROLUMINESCENT DISPLAY PANEL, FABRICATING METHOD THEREOF AND DISPLAY DEVICE

(71) Applicant: BOE TECHNOLOGY GROUP CO., LTD., Beijing (CN)

(72) Inventors: Dan WANG, Beijing (CN); Wei ZHANG, Beijing (CN)

(21) Appl. No.: 15/209,590

(22) Filed: Jul. 13, 2016

(30) Foreign Application Priority Data
Jan. 5, 2016 (CN) 201610007006.0

(51) Int. Cl. H01L 27/32; H01L 51/52; H01L 51/56; H01L 51/00

(52) U.S. Cl. CPC H01L 27/3237; H01L 51/0097; H01L 51/5275; H01L 51/56; H01L 51/5203

(57) ABSTRACT

An electroluminescent display panel, a fabricating method thereof and a display device are disclosed. in the electroluminescence display panel, a surface of the substrate contacting the first electrode layer is provided with a groove structure arranged in correspondence with the organic light emitting structure, a transparent filling layer is arranged in the groove structure, and a refractive index of the filling layer is greater than that of the first electrode layer and different from that of the substrate. Under the refraction effect of the groove structure, the incident angle of the light emitted by each organic light emitting structure to the substrate is reduced, the possiblity of total reflection of light entering the substrate from the first electrode layer is reduced, and extraction efficiency of light emitted by each organic light emitting structure is increased.

### RELATED APPLICATIONS

The present application claims the benefit of Chinese Patent Application No. 201610007006.0, filed Jan. 5, 2016, the entire disclosure of which is incorporated herein by reference.

### TECHNICAL FIELD

The present invention relates to the field of display technology, particularly to an electroluminescent display panel, a fabricating method thereof and a display device.

### BACKGROUND

At present, the organic light emitting display device, as the mainstream development direction of the next generation of display and lighting technology, has the advantages of active luminescence, wide color gamut, fast response, wide visual angle, high contrast, and planarization etc. In order to increase the light extraction efficiency of the organic light emitting display device, one way is inner extraction, in which a scattering layer or a micro lens film layer is mainly attached to the light emitting surface of the substrate to reduce total reflection of the glass baseplate to the air; the other way is external extraction, in which a light scattering layer is introduced within the organic light emitting display device, such as introducing a light scattering layer or a grating structure at the interface of the glass baseplate and the transparent conductive layer so as to increase the extraction efficiency when the light passes through this interface. In such existing ways of increasing light extraction efficiency, because film layers have to be added, the flexibility of the organic light emitting display device will be reduced.

### SUMMARY

An object of embodiments of the present invention is to provide an electroluminescent display panel, a fabricating method thereof and a display device, for solving one or more of the above problems or other problems.

An electroluminescence display panel comprises a transparent substrate, a plurality of organic light emitting diodes (OLEDs) on the substrate; each OLED comprising a transparent first electrode layer on the substrate, an organic light emitting structure on the first electrode layer, and a second electrode layer on the organic light emitting structure. A groove structure corresponding to the organic light emitting structure is arranged on a surface of the substrate contacting the first electrode layer. A transparent filling layer is arranged in the groove structure. A refractive index of the filling layer is greater than that of the first electrode layer and different from that of the substrate.

For example, the second electrode layer is reflective or transparent.

For example, an upper surface of the filling layer is flush with that of the substrate.

For example, an orthographic projection of the groove structure on the substrate covers that of the organic light emitting structure on the substrate.

For example, an area of the orthographic projection of the groove structure on the substrate is 1 to 1.5 times that of the orthographic projection of the organic light emitting structure on the substrate.

For example, a shape of the orthographic projection of the groove structure on the substrate is a circle, a square or a rectangle.

For example, a shape of the orthographic projection of the organic light emitting structure on the substrate is a square; a shape of the orthographic projection of the groove structure on the substrate is a circle.

For example, the square has a width of 10 μm to 25 μm, and the circle has a diameter of 20 μm to 30 μm.

For example, the substrate is a flexible substrate.

For example, the substrate is a polyimide substrate.

For example, a depth of the groove structure is less than ⅔ of a thickness of the substrate.

For example, a material of the filling layer is a glass cement material.

A display device comprises an electroluminescence display panel as stated in any of the above.

A fabricating method of an electroluminescence display panel as stated in any of the above, the fabricating method comprises:

forming a groove structure on a substrate;

forming a filling layer in the groove structure; and

forming a first electrode layer, an organic light emitting structure and a second electrode layer on the filling layer which correspond to the groove structure.

For example, the step of forming the groove structure on the substrate comprises: coating a polyimide solution on a glass baseplate to form the substrate.

After forming the first electrode layer, the organic light emitting structure and the second electrode layer on the filling layer which correspond to the groove structure, the method further comprises: removing the glass baseplate under the substrate by means of laser.

For example, the step of forming the filling layer on the groove structure comprises: filling and sintering glass cement in the groove structure to form the filling layer.

In the electroluminescent display panel, the fabricating method thereof and the display device provided by embodiments of the present invention, since a groove structure corresponding to each organic light emitting structure is arranged at the surface of the substrate contacting the first electrode layer, and a transparent filling layer is arranged in the groove structure, under the refraction effect of the groove structure, the incident angle of the light emitted by each organic light emitting structure to the substrate is reduced, the possiblity of total reflection of light entering the substrate from the first electrode layer is reduced, and extraction efficiency of light emitted by each organic light emitting structure is increased, consequently, the whole light extraction efficiency is increased; moreover, since the groove structure is arranged within the substrate, the upper surface of the filling layer and the upper surface of the substrate has the equal height, thus, the thickness of the whole film layer will not be increased and the flexibility of the electroluminescent display panel will not be reduced.

### BRIEF DESCRIPTION OF THE DRAWINGS

FIG. 1 is a structural schematic view of an electroluminescent display panel provided by an embodiment of the present invention;

FIG. 2 is a flow chart of a fabricating method of an electroluminescent display panel provided by an embodiment of the present invention;

FIG. 3 is a schematic view of process flow of forming a substrate provided by an embodiment of the present invention;

FIG. 4 is a schematic view of process flow of forming a groove structure provided by an embodiment of the present invention;

FIG. 5 is a schematic view of process flow of forming a filling layer provided by an embodiment of the present invention;

FIG. 6 is a schematic view of process flow of forming an OLED provided by an embodiment of the present invention; and

FIG. 7 is a vertical schematic view of an organic light emitting structure and a groove structure provided by an embodiment of the present invention.

### DETAILED DESCRIPTION OF EMBODIMENTS

Next, the electroluminescent display panel, the fabricating method thereof and the display device provided by the present invention will be explained in more detail with reference to the drawings and the embodiments. The thickness of the film layers in the drawings do not represent real thickness and proportion of the electroluminescent display panel.

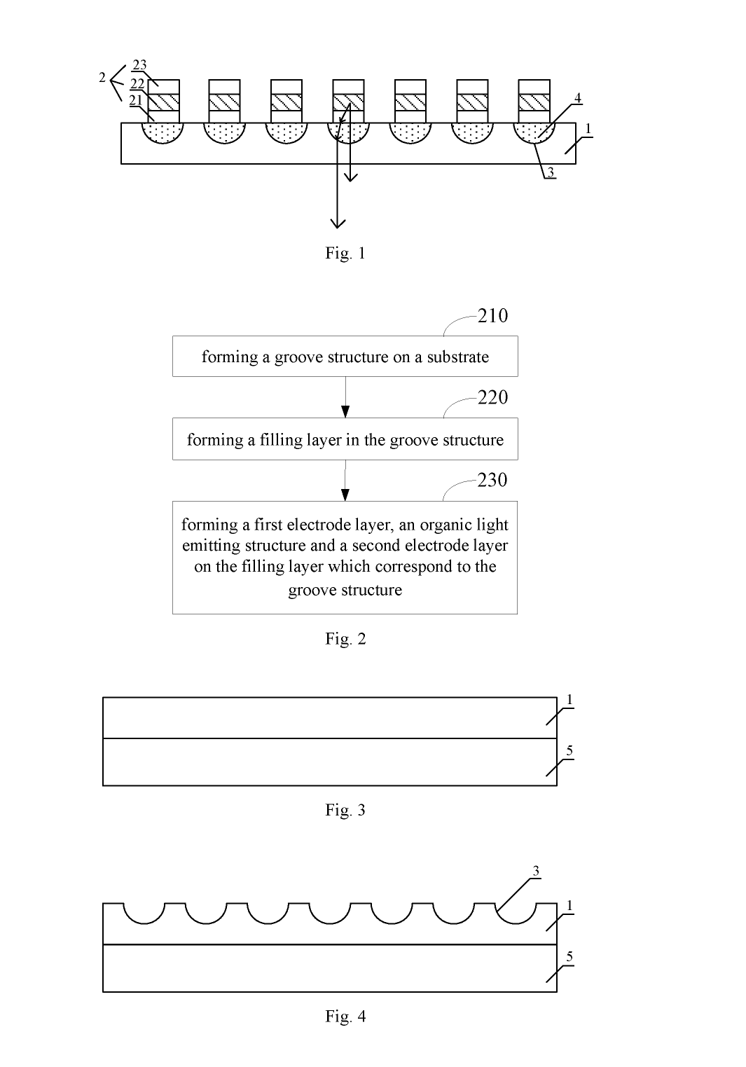

As shown in FIG. 1, an embodiment of the present invention provides an electroluminescent display panel, comprising a transparent substrate 1, and a plurality of organic light emitting diodes (OLEDs) 2 on the substrate 1. Each OLED 2 comprises a transparent anode layer 21 on the substrate 1, an organic light emitting structure 22 on the anode layer 21, and a cathode layer 23 on the organic light emitting structure 22. A groove structure 3 corresponding to the organic light emitting structure 22 is arranged on a surface of the substrate 2 contacting the anode layer 21. A transparent filling layer 4 is arranged in the groove structure 3. An upper surface of the filling layer is flush with that of the substrate. A refractive index of the filling layer 4 is greater than that of the anode layer 21 and different from that of the substrate 1.

The arrows in FIG. 1 indicate the direction of the light path.

In the above embodiments, reference is make to a reflective anode layer 21 and a transparent substrate 1. In this case, the OLED is of a bottom emitting type. In other embodiments, both the anode layer 21 and the substrate 1 are transparent, and accordingly the OLED is of a dual-side emitting type. Namely, the concept of embodiments of the present invention is not only applicable to a bottom emitting OLED, but also to a dual-side emitting OLED.

In the embodiment of the present invention, since a groove structure 3 corresponding to each organic light emitting structure 22 is arranged at the surface of the substrate 1 contacting the anode layer 21, and a transparent filling layer 4 is arranged in the groove structure 3, under the refraction effect of the groove structure 3, the incident angle of the light emitted by each organic light emitting structure 22 to the substrate 1 is reduced, the possiblity of total reflection of light entering the substrate 1 from the anode layer 21 is reduced, and extraction efficiency of light emitted by each organic light emitting structure 22 is increased, consequently, the whole light extraction efficiency is increased; moreover, since the groove structure 3 is arranged within the substrate 1, the upper surface of the filling layer 4 and the upper surface of the substrate 1 has the equal height, thus, the thickness of the whole film layer will not be increased and the flexibility of the electroluminescent display panel will not be reduced.

For example, an orthographic projection of the groove structure 3 on the substrate 1 covers that of the organic light emitting structure 22 on the substrate 1.

In this embodiment, enabling the orthogonal projection of the groove structure 3 on the substrate 1 to be greater than the orthogonal projection of the organic light emitting structure 22 on the substrate 1 is benefit for extracting as much as possible light emitted by each organic light emitting structure 22, so as to improve the whole light extraction efficiency.

For example, an area of the orthographic projection of the groove structure 3 on the substrate 1 is 1 to 1.5 times that of the orthographic projection of the organic light emitting structure 22 on the substrate 1.

Based on any of the above embodiments, the groove structure 3 has various shapes, for example, the shape of the orthogoral projection of the groove structure 3 on the substrate 1 can be a circle, a square or a rectangle.

In a possible embodiment, the shape of the orthographic projection of the organic light emitting structure 22 on the substrate 1 is a square; the shape of the orthographic projection of the groove structure 3 on the substrate 1 is a circle.

For example, when the shape of the orthographic projection of the organic light emitting structure 22 on the substrate 1 is a square, it has a width of 10 μm to 25 μm; when the shape of the orthographic projection of the groove structure 3 on the substrate 1 is a circle, it has a diameter of 20 μm to 30 μm.

Based on any of the above embodiments, for example, the above substrate 1 is a flexible substrate, which is benefit for improving flexibility of the electroluminescent display panel.

There are various materials that enable the substrate 1 to be a flexible substrate. For example, the above substrate 1 is a polyimide PI substrate.

If the substrate 1 is a flexible substrate, in order to ensure mechanical strength of the substrate 1, the groove structure 3 should not be too deep, for example, the depth of the groove structure 3 is less than ⅔ of the thickness of the substrate 1.

Because the material of the filling layer 4 needs a good light transmittance and a high refractive index, based on any of the above embodiments, for example, the material of the filling layer is a glass cement material.

Based on the same inventive concept, an embodiment of the present invention provides a method for fabricating an electroluminescence display panel as stated in any of the above embodiments, as shown in FIG. 2, the method comprises:

Step 210: forming a groove structure on a substrate;

Step 220: forming a filling layer in the groove structure;

Step 230: forming a first electrode layer, an organic light emitting structure and a second electrode layer on the filling layer which correspond to the groove structure.

In the following embodiment, the first electrode layer is an anode layer, and the second electrode layer is a cathode layer. However, it is appreciated that in other embodiments, the first electrode layer is a cathode layer, and the second electrode layer is an anode layer. In case the cathode layer, the organic light emitting structure and the anode layer are formed on the filling layer in sequence, the cathode layer is transparent, and the anode is transparent or reflective.

For example, a groove structure is formed on the substrate in step 210, specifically: coating a polyimide solution on a glass baseplate to form the substrate. Correspondingly, after forming the anode layer, the organic light emitting structure and the cathode layer on the filling layer which correspond to the groove structure, the method further comprises: removing the glass baseplate under the substrate by means of laser.

For example, a filling layer is formed in the groove structure in step 220, specifically: filling and sintering glass cement in the groove structure to form the filling layer.

Next, an electroluminescent display panel and a fabricating method thereof provided by embodiments of the present invention will be explained in more detail by taking the example that the substrate is a PI substrate.

Step I: as shown in FIG. 3, a PI solution is coated on a glass baseplate 5, to obtain a substrate 1 through drying and shaping.

Step II: as shown in FIG. 4, a groove structure 3 is formed by dry etching at position where an OLED is to be formed on the substrate 1

In the process of etching the groove structure, the condition of PI etching is controllable. The shape and depth of the etching can be controlled by adjusting the size of the mask to be used and the etching time. The optimal light extraction effect is achieved while ensuring the mechanical strength of the substrate 1.

In this embodiment, the etched groove structure 3 is in a spherical shape, the orthogonal projection on the substrate 1 is a circle, the diameter of which is 20 μm to 30 μm.

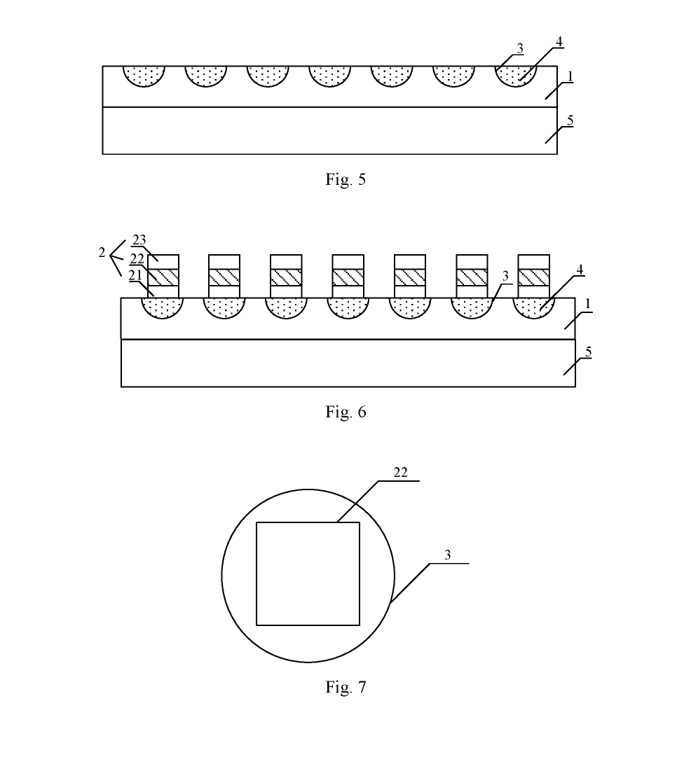

Step III: as shown in FIG. 5, each groove structure 3 on the substrate 1 is filled with glass cement by dropping, and the organic dispersant therein is removed by sintering, so as to the surface of the substrate 1 is smooth, thereby forming the filling layer 4.

The main component of the glass cement can be oxide or compound of elements such as Bi, B, Zn, Si.

Step IV: as shown in FIG. 6, an anode layer 21, an organic light emitting structure 22 and a cathode layer 23 which correspond to the groove structure 3 are formed on the filling layer 4.

In this step, an OLED 2 corresponding to each groove structure 3 is formed. The region of the orthogonal projection of the groove structure 3 on the substrate 1 covers the region of the orthogonal projection of the organic light emitting structure 22 on the substrate. The shape of the orthogonal projection of the organic light emitting structure 22 on the substrate 1 is a square, the width thereof is 10 μm to 25 μm.

Optionally, the area of the orthogonal projection of the groove structure 3 on the substrate 1 is 1.2 times of the area of the orthogonal projection of the organic light emitting structure 22 on the substrate 1. As shown in FIG. 7, it is a vertical schematic view of the organic light emitting structure 22 and the groove structure 3.

Step V: removing the glass baseplate 5 under the substrate 1 by means of laser.

Based on the same inventive concept, an embodiment of the present invention provides a display device comprising an electroluminescent display panel as stated in any of the above embodiments.

In the electroluminescent display panel, the fabricating method thereof and the display device provided by embodiments of the present invention, since a groove structure corresponding to each organic light emitting structure is arranged at the surface of the substrate contacting the anode layer, and a transparent filling layer is arranged in the groove structure, under the refraction effect of the groove structure, the incident angle of the light emitted by each organic light emitting structure to the substrate is reduced, the possiblity of total reflection of light entering the substrate from the anode layer is reduced, and extraction efficiency of light emitted by each organic light emitting structure is increased, consequently, the whole light extraction efficiency is increased; moreover, since the groove structure is arranged within the substrate, the upper surface of the filling layer and the upper surface of the substrate has the equal height, thus, the thickness of the whole film layer will not be increased and the flexibility of the electroluminescent display panel will not be reduced.

Although the preferred embodiments of the present invention have been described, once the skilled person in the art learns the basic inventive concept, he/she would be able to make additional variations and modifications to these embodiments. So, the claims attached intend to be construed as including the preferred embodiments and all the variations and modifications that fall within the scope of the present invention.

Apparently, the skilled person in the art can make various modifications and variations to the present invention without departing from the spirit and the scope of the present invention. In this way, provided that these modifications and variations of the present invention belong to the scopes of the claims of the present invention and the equivalent technologies thereof, the present invention also intends to encompass these modifications and variations.

What is claimed is:

1. An electroluminescence display panel, comprising a transparent substrate, and a plurality of organic light emitting diodes on the substrate, wherein each organic light emitting diode comprises a transparent first electrode layer on the substrate, an organic light emitting structure on the first electrode layer, and a second electrode layer on the organic light emitting structure,
wherein a groove structure corresponding to the organic light emitting structure is arranged on a surface of the substrate contacting the first electrode layer; a transparent filling layer is arranged in the groove structure; and a refractive index of the filling layer is greater than that of the first electrode layer and different from that of the substrate.

2. The electroluminescence display panel of claim 1, wherein the second electrode layer is reflective or transparent.

3. The electroluminescence display panel of claim 1, wherein an upper surface of the filling layer is flush with that of the substrate.

4. The electroluminescence display panel of claim 1, wherein an orthographic projection of the groove structure on the substrate covers that of the organic light emitting structure on the substrate.

5. The electroluminescence display panel of claim 4, wherein an area of the orthographic projection of the groove structure on the substrate is 1 to 1.5 times that of the orthographic projection of the organic light emitting structure on the substrate.

6. The electroluminescence display panel of claim 5, wherein a shape of the orthographic projection of the groove structure on the substrate is a circle, a square or a rectangle.

7. The electroluminescence display panel of claim 6, wherein a shape of the orthographic projection of the organic light emitting structure on the substrate is a square, and a shape of the orthographic projection of the groove structure on the substrate is a circle.

8. The electroluminescence display panel of claim 7, wherein the square has a width of 10 μm to 25 μm, and the circle has a diameter of 20 μm to 30 μm.

9. The electroluminescence display panel of claim 1, wherein the substrate is a flexible substrate.

10. The electroluminescence display panel of claim 9, wherein the substrate is a polyimide substrate.

11. The electroluminescence display panel of claim 9, wherein a depth of the groove structure is less than ⅔ of a thickness of the substrate.

12. The electroluminescence display panel of claim 1, wherein a material of the filling layer is a glass cement material.

13. The electroluminescence display panel of claim 1, wherein the first electrode layer is an anode layer, and the second electrode layer is a cathode layer.

14. A display device, comprising an electroluminescence display panel, wherein the electroluminescence display panel comprises a transparent substrate, and a plurality of organic light emitting diodes on the substrate, wherein each organic light emitting diode comprises a transparent first electrode layer on the substrate, an organic light emitting structure on the first electrode layer, and a second electrode layer on the organic light emitting structure,
wherein a groove structure corresponding to the organic light emitting structure is arranged on a surface of the substrate contacting the first electrode layer, a transparent filling layer is arranged in the groove structure, and a refractive index of the filling layer is greater than that of the first electrode layer and different from that of the substrate.

15. The display device of claim 14, wherein the second electrode layer is reflective or transparent.

16. The display device of claim 14, wherein an upper surface of the filling layer is flush with that of the substrate.

17. A method for fabricating an electroluminescence display panel of claim 1, wherein the method comprises steps of:
forming a groove structure on a substrate;
forming a filling layer in the groove structure; and
forming a first electrode layer, an organic light emitting structure and a second electrode layer on the filling layer which correspond to the groove structure.

18. The method of claim 17, wherein the step of forming the groove structure on the substrate comprises:
coating a polyimide solution on a glass baseplate to form the substrate.

19. The method of claim 18, wherein after forming the first electrode layer, the organic light emitting structure and the second electrode layer on the filling layer which correspond to the groove structure, the method further comprises:
removing the glass baseplate under the substrate by means of laser.

20. The method of claim 18, wherein the step of forming the filling layer on the groove structure comprises:
filling and sintering glass cement in the groove structure to form the filling layer.
